(19) United States
(12) Patent Application Publication
(10) Pub. No.: US 2016/0205778 A1
(43) Pub. Date: Jul. 14, 2016

(54) WIRING BOARD WITH EMBEDDED INTERPOSER INTEGRATED WITH STIFFENER AND METHOD OF MAKING THE SAME

(71) Applicant: BRIDGE SEMICONDUCTOR CORPORATION, Taipei (TW)

(72) Inventors: Charles W. C. Lin, Singapore (SG); Chia-Chung Wang, Hsinchu County (TW)

(21) Appl. No.: 14/996,208

(22) Filed: Jan. 14, 2016

Related U.S. Application Data
(60) Provisional application No. 62/103,526, filed on Jan. 14, 2015.
(60) Provisional application No. 62/106,600, filed on Jan. 22, 2015.

(51) Int. Cl. H05K 1/11; H01L 21/48; H05K 3/40; H01L 23/498

(52) U.S. Cl. CPC H05K 1/112; H01L 23/49811; H01L 23/49827; H01L 23/49894; H01L 21/4846; H01L 21/486; H01L 21/4853; H01L 21/4875; H05K 3/4038; H05K 3/4007

(57) ABSTRACT

A wiring board with embedded interposer is characterized in that the embedded interposer is integrated with a stiffener and a build-up circuitry is deposited on the stiffener, so that the mechanical robustness of the stiffener can prevent the entire wiring board from warping. The interposer provides primary fan-out routing whereas the build-up circuitry provides further fan-out routing and can further enlarge the pad size and pitch of the interposer.

### CROSS REFERENCE TO RELATED APPLICATIONS

This application claims the benefit of filing date of U.S. Provisional Application Ser. No. 62/103,526 filed Jan. 14, 2015 and the benefit of the filing date of U.S. Provisional Application Ser. No. 62/106,600 filed Jan. 22, 2015. The entirety of said Provisional Applications is incorporated herein by reference.

### FIELD OF THE INVENTION

The present invention relates to a wiring board, more particularly, to a wiring board with embedded interposer integrated with resin molded stiffener, and a method of making the same.

### DESCRIPTION OF RELATED ART

For high pin-count semiconductor chip packaging and assembly, high-density wiring board is needed for mounting a semiconductor chip thereon so that chip I/O pads can be routed to a much large pitch for reliable board-level assembly. For example, U.S. Pat. Nos. 9,060,455, 9,089,041, 8,859,912 and 8,797,757 disclose various coreless substrates for chip fan-out routing purposes. Coreless substrate has several advantages over core-substrate including lower parasitic resistance, lower inductance and capacitance. Most importantly, the interconnect density of coreless substrate is much higher than that of the conventional core substrate, which is a key feature for fine pitch and high I/O applications. However, as coreless substrate tends to warp during the repeated heating and cooling in the process of manufacturing, it is not commonly adopted yet. U.S. Pat. Nos. 8,860,205, 7,981,728 and 7,902,660 intend to solve this issue but with little success.

Worse, as semiconductor chips have a low coefficient of thermal expansion (Si˜3 to 4 ppm) compared to that of the organic substrate (epoxy resin˜15 ppm), interfacial stress due to mismatched-CTE often causes poor chip-level connection reliability.

For the reasons stated above, and for other reasons stated below, an urgent need exists to provide a new wiring board that can address high performance IC packaging's needs with better signal integrity, higher production yield, higher reliability and lower cost.

### SUMMARY OF THE INVENTION

A primary objective of the present invention is to provide a wiring board in which an inorganic interposer is incorporated in the wiring board for semiconductor chip attachment so that the low-CTE and high-modulus interposer can ensure a reliable interface for chip connection.

Another objective of the present invention is to provide a wiring board in which the interposer is integrated with a resin molded stiffener so that the warping and bending of the wiring board can be suppressed, thereby improving the mechanical reliability of the wiring board.

Yet another objective of the present invention is to provide a wiring board in which the resin molded stiffener includes a base and a protruded portion projecting from the base, thereby offering critical stiffness enhancement for the base and the embedded interposer.

Yet another objective of the present invention is to provide a wiring board in which the interposer is electrically coupled with a build-up circuitry so that staged fan-out routing can be provided, thereby improving production yield and lowering the cost.

In accordance with the foregoing and other objectives, the present invention provides a wiring board that includes a resin molded stiffener, an interposer and a build-up circuitry. In a preferred embodiment, the resin molded stiffener includes a base and a protruded portion projecting from a first surface of the base and provides a high modulus anti-warping platform for the interposer and the build-up circuitry; the interposer, laterally surrounded by the base of the resin molded stiffener, provides primary fan-out routing for a chip to be assembled thereon so that the possible bond pad disconnection induced by tight I/O pad pitch can be avoided; and the build-up circuitry, disposed over an opposite second surface of the base and electrically coupled to the interposer, provides secondary fan-out routing so that the pad size and pitch of the interposer can be further enlarged.

In another aspect, the present invention provides a wiring board with embedded interposer integrated with stiffener, comprising: a resin molded stiffener that includes a base and a protruded portion projecting from a first surface of the base; an interposer that includes bond pads at a first surface thereof, contact pads at an opposite second surface thereof, and metallized vias electrically coupled to the bond pads and the contact pads, wherein the interposer is laterally surrounded by the base with the first surface of the interposer facing the same direction as the first surface of the base and being not covered by the base; and a build-up circuitry over an opposite second surface of the base, wherein the build-up circuitry is electrically coupled to the contact pads of the interposer and includes at least one conductive trace laterally extending beyond peripheral edges of the interposer.

In yet another aspect, the present invention provides a method of making a wiring board with embedded interposer integrated with stiffener, comprising steps of: providing a semi-finished interposer that includes a substrate having a first surface and an opposite second surface, bond pads at the first surface of the substrate, and metallized vias, each of which is formed in the substrate and has a first end electrically coupled to the bond pads and an opposite second end spaced from the second surface of the substrate; attaching the semi-finished interposer on a sacrificial carrier using an adhesive, with the first surface of the substrate facing the sacrificial carrier; forming a resin molded stiffener that covers the sacrificial carrier and laterally surrounds the semi-finished interposer and the sacrificial carrier; removing portions of the resin molded stiffener and the semi-finished interposer to expose the second ends of the metallized vias with the substrate having an exposed second surface substantially coplanar with the second ends of the metallized vias; forming contact pads at the exposed second surface of the substrate to finish fabrication of an interposer that includes the bond pads and the contact pads respectively on opposite first and second surfaces thereof and the metallized vias electrically coupled to the bond pads and the contact pads; forming a build-up circuitry that covers the second surface of the interposer and the resin molded stiffener and is electrically coupled to the contact pads of the interposer and includes at least one conductive trace laterally extending beyond peripheral edges of the interposer; and removing the sacrificial carrier and the adhesive to expose the bond pads of the interposer.

In yet another aspect, the present invention provides another method of making a wiring board with embedded interposer integrated with stiffener, comprising steps of: providing an interposer that includes bond pads at a first surface thereof, contact pads at an opposite second surface thereof, and metallized vias electrically coupled to the bond pads and the contact pads; attaching the interposer on a sacrificial carrier using an adhesive, with the first surface of the interposer facing the sacrificial carrier; forming a resin molded stiffener that covers the sacrificial carrier and laterally surrounds the interposer and the sacrificial carrier; forming a build-up circuitry that covers the second surface of the interposer and the resin molded stiffener and is electrically coupled to the contact pads of the interposer and includes at least one conductive trace laterally extending beyond peripheral edges of the interposer; and removing the sacrificial carrier and the adhesive to expose the bond pads of the interposer.

Unless specifically indicated or using the term “then” between steps, or steps necessarily occurring in a certain order, the sequence of the above-mentioned steps is not limited to that set forth above and may be changed or reordered according to desired design.

The method of making a wiring board according to the present invention has numerous advantages. For instance, integrating the resin molded stiffener with the sacrificial carrier and the finished or semi-finished interposer before the formation of the build-up circuitry is particularly advantageous as the resin molded stiffener together with the sacrificial carrier provides a stable platform for forming the build-up circuitry, and serious warping problem can be avoided when multiple layers of wiring layers are need. Additionally, the two-stage formation of the interconnect substrate for a chip is beneficial as the interposer can provide primary fan-out routing and a CTE-matched interface whereas the build-up circuitry provide further fan-out routing and horizontal interconnections between the upper and the lower devices.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and bottom perspective views, respectively, of a substrate having blind vias formed therein in accordance with the first embodiment of the present invention;

FIG. 3 is a cross-sectional view showing that the structure of FIG. 1 is provided with metallized vias in accordance with the first embodiment of the present invention;

FIGS. 4 and 5 are cross-sectional and bottom perspective views, respectively, showing that the structure of FIG. 3 is provided with routing traces to finish the fabrication of a semi-finished interposer panel in accordance with the first embodiment of the present invention;

FIGS. 6 and 7 are cross-sectional and bottom perspective views, respectively, of a diced state of the panel-scale structure of FIGS. 4 and 5 in accordance with the first embodiment of the present invention;

FIGS. 8 and 9 are cross-sectional and bottom perspective views, respectively, of a semi-finished interposer corresponding to a diced unit in FIGS. 6 and 7 in accordance with the first embodiment of the present invention;

FIGS. 10 and 11 are cross-sectional and top perspective views, respectively, of a sacrificial carrier with alignment guides formed thereon in accordance with the first embodiment of the present invention;

FIG. 12 is a cross-sectional view showing that the semi-finished interposers of FIG. 8 are attached to the sacrificial carrier of FIG. 10 using an adhesive, in accordance with the first embodiment of the present invention;

FIGS. 13 and 14 are cross-sectional and top perspective views, respectively, of a diced state of the panel-scale structure of FIG. 12 in accordance with the first embodiment of the present invention;

FIG. 15 is a cross-sectional view showing that subcomponents corresponding to diced units in FIG. 13 are attached to a carrier film in accordance with the first embodiment of the present invention;

FIG. 16 is a cross-sectional view showing that the structure of FIG. 15 is provided with a resin molded stiffener in accordance with the first embodiment of the present invention;

FIG. 17 is a cross-sectional view showing the structure of FIG. 16 is partially removed in accordance with the first embodiment of the present invention;

FIGS. 18 and 19 are cross-sectional and top perspective views, respectively, showing that the structure of FIG. 17 is provided with routing traces in accordance with the first embodiment of the present invention;

FIG. 20 is a cross-sectional view showing that the structure of FIG. 18 is provided with a dielectric layer and via openings in accordance with the first embodiment of the present invention;

FIG. 21 is a cross-sectional view showing that the structure of FIG. 20 is provided with conductive traces in accordance with the first embodiment of the present invention;

FIG. 22 is a cross-sectional view showing that the carrier film and the sacrificial carrier are removed from the structure of FIG. 21 in accordance with the first embodiment of the present invention;

FIGS. 23 and 24 are cross-sectional and bottom perspective views, respectively, showing that the adhesive is removed from the structure of FIG. 22 to finish the fabrication of a wiring board in accordance with the first embodiment of the present invention;

FIG. 25 is a cross-sectional view of the structure with semiconductor devices mounted on the wiring board of FIG. 23 in accordance with the first embodiment of the present invention;

FIG. 26 is a cross-sectional view of a diced state of the panel-scale structure of FIG. 25 in accordance with the first embodiment of the present invention;

FIG. 27 is a cross-sectional view of a semiconductor assembly corresponding to a diced unit in FIG. 26 in accordance with the first embodiment of the present invention;

FIG. 28 is a cross-sectional view of alignment guides on a sacrificial carrier in accordance with the second embodiment of the present invention;

FIG. 29 is a cross-sectional view showing that the semi-finished interposers of FIG. 8 are attached to the sacrificial carrier of FIG. 28 using an adhesive in accordance with the second embodiment of the present invention;

FIG. 30 is a cross-sectional view showing that the structure of FIG. 29 is provided with a resin molded stiffener in accordance with the second embodiment of the present invention;

FIG. 31 is a cross-sectional view showing that the structure of FIG. 30 is partially removed in accordance with the second embodiment of the present invention;

FIG. 32 is a cross-sectional view showing that the structure of FIG. 31 is provided with routing traces in accordance with the second embodiment of the present invention;

FIG. 33 is a cross-sectional view showing that the structure of FIG. 32 is provided with a dielectric layer and via openings in accordance with the second embodiment of the present invention;

FIG. 34 is a cross-sectional view showing that the structure of FIG. 33 is provided with conductive traces in accordance with the second embodiment of the present invention;

FIG. 35 is a cross-sectional view showing that the sacrificial carrier and the adhesive are removed from the structure of FIG. 34 in accordance with the second embodiment of the present invention;

FIG. 36 is a cross-sectional view of a diced state of the panel-scale structure of FIG. 35 in accordance with the second embodiment of the present invention;

FIG. 37 is a cross-sectional view of a wiring board corresponding to a diced unit in FIG. 36 in accordance with the second embodiment of the present invention;

FIG. 38 is a cross-sectional view of a semiconductor assembly with semiconductor devices mounted on the wiring board of FIG. 37 in accordance with the second embodiment of the present invention;

FIGS. 39 and 40 are cross-sectional and top perspective views, respectively, of an alignment guide on a sacrificial carrier in accordance with the third embodiment of the present invention;

FIGS. 41 and 42 are cross-sectional and top perspective views, respectively, showing that an interposer is attached to the sacrificial carrier of FIGS. 39 and 40 using an adhesive, in accordance with the third embodiment of the present invention;

FIG. 43 is a cross-sectional view showing that the structure of FIG. 41 is provided with a resin molded stiffener in accordance with the third embodiment of the present invention;

FIG. 44 is a cross-sectional view showing that the structure of FIG. 43 is partially removed in accordance with the third embodiment of the present invention;

FIG. 45 is a cross-sectional view showing that the structure of FIG. 44 is provided with conductive traces in accordance with the third embodiment of the present invention;

FIG. 46 is a cross-sectional view showing that the sacrificial carrier and the adhesive are removed from the structure of FIG. 45 to finish the fabrication of a wiring board in accordance with the third embodiment of the present invention;

FIG. 47 is a cross-sectional view of an interposer on a sacrificial carrier in accordance with the fourth embodiment of the present invention;

FIG. 48 is a cross-sectional view showing that the structure of FIG. 47 is attached to a carrier film and provided with a resin molded stiffener in accordance with the fourth embodiment of the present invention;

FIG. 49 is a cross-sectional view showing that the structure of FIG. 48 is partially removed in accordance with the fourth embodiment of the present invention;

FIG. 50 is a cross-sectional view showing that the structure of FIG. 49 is provided with a dielectric layer and a metal layer in accordance with the fourth embodiment of the present invention;

FIG. 51 is a cross-sectional view showing that the structure of FIG. 50 is provided with via openings in accordance with the fourth embodiment of the present invention;

FIG. 52 is a cross-sectional view showing that the structure of FIG. 51 is provided with conductive traces in accordance with the fourth embodiment of the present invention; and

FIG. 53 is a cross-sectional view showing that the carrier film, the sacrificial carrier and the adhesive are removed from the structure of FIG. 52 to finish the fabrication of a wiring board in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

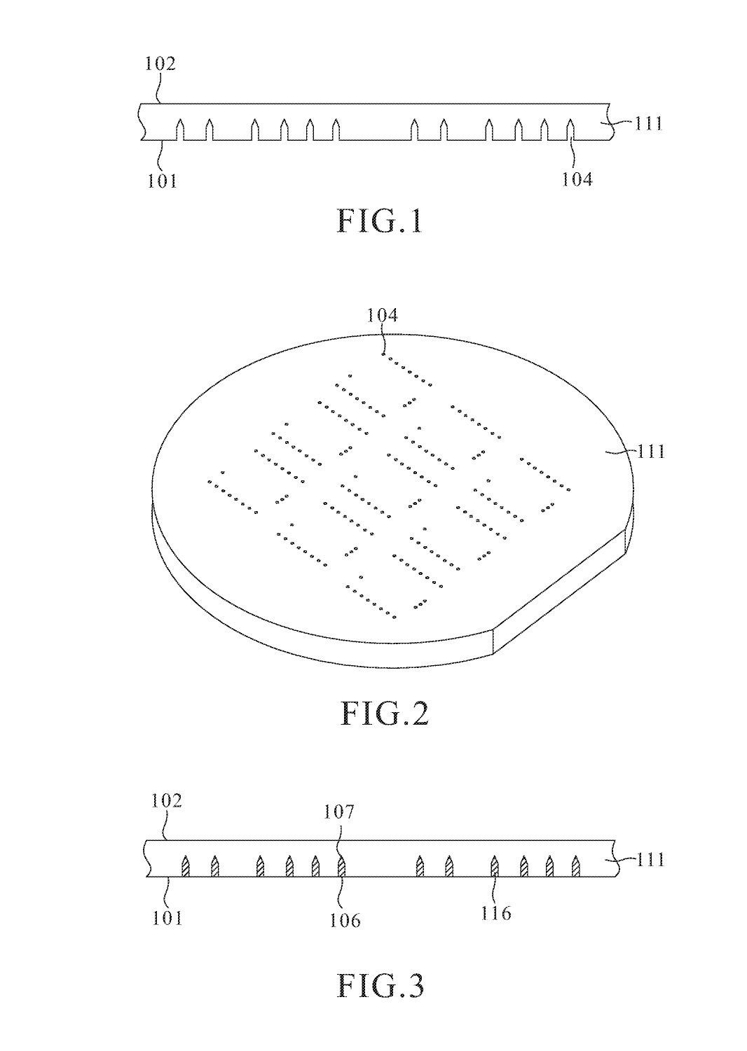

FIGS. 1-24 are schematic views showing a method of making a wiring board that includes interposers 11, alignment guides 14, a resin molded stiffener 30 and a build-up circuitry 40 in accordance with the first embodiment of the present invention.

FIGS. 1 and 2 are cross-sectional and bottom perspective views, respectively, of a substrate 111 having a first surface 101, an opposite second surface 102, and blind vias 104 formed in the first surface 101. The substrate 111 can be made of silicon, glass or ceramic and have a thickness of 50 microns to 500 microns. The blind vias 104 can have a depth of 25 microns to 250 microns. In this embodiment, the substrate 111 is a silicon wafer and has a thickness of 200 microns, and the blind vias 104 are formed with a depth of 150 microns.

FIG. 3 is a cross-sectional view of the structure provided with metallized vias 116. The metallized vias 116 are formed in the substrate 111 by metal deposition in the blind vias 104. Each metallized via 116 has a first end 106 substantially coplanar with the first surface 101 of the substrate 111 and an opposite second surface 107 spaced from the second surface surface 102 of the substrate 111. For the aspect of using a silicon substrate, an insulative/passivation layer such as a silicon oxide layer (not shown in the figures) is needed on the sidewalls of the blind vias 104 before metal deposition as silicon is a semiconductor material.

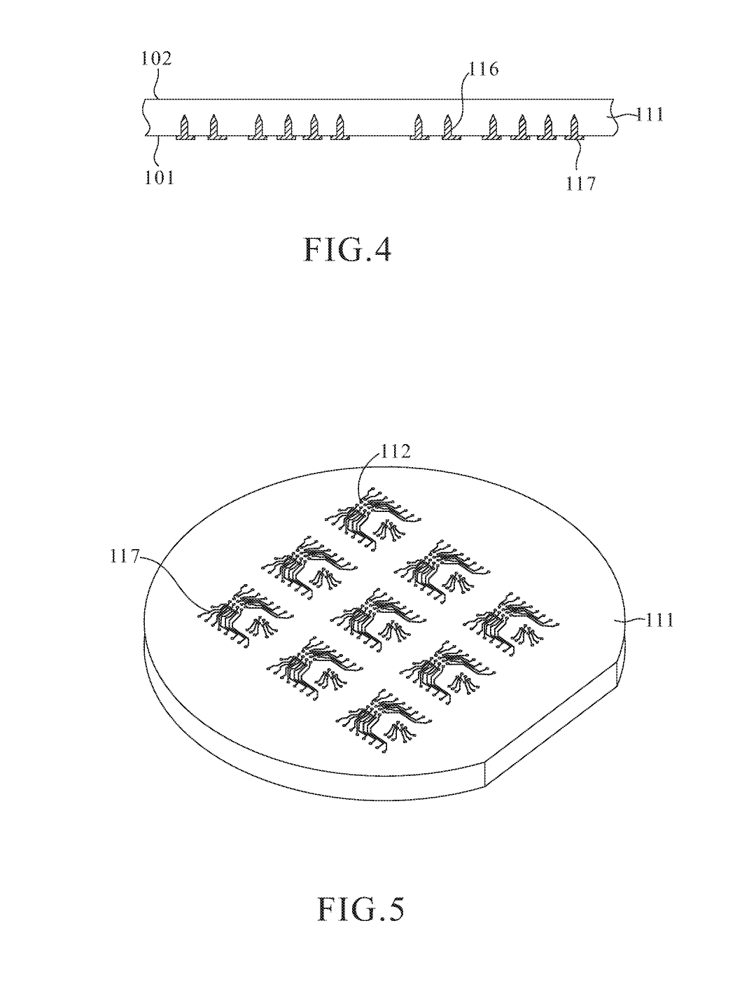

FIGS. 4 and 5 are cross-sectional and bottom perspective views, respectively, of the structure having bottom routing traces 117 at the first surface 101 of the substrate 111. The first surface 101 of the substrate 111 can be metallized by numerous techniques, such as electroplating, electroless plating, evaporating, sputtering, or their combinations. Once the desired thickness is achieved, a metal patterning process is executed to form the bottom routing traces 117 electrically coupled to the first ends 106 of the metallized vias 116. As shown in FIG. 5, the bottom routing traces 117 include a patterned array of bond pads 112 that match chip I/O pads. Similarly, for a silicon substrate, an insulative/passivation layer (not shown in the figures) is needed on the substrate surface before routing trace formation.

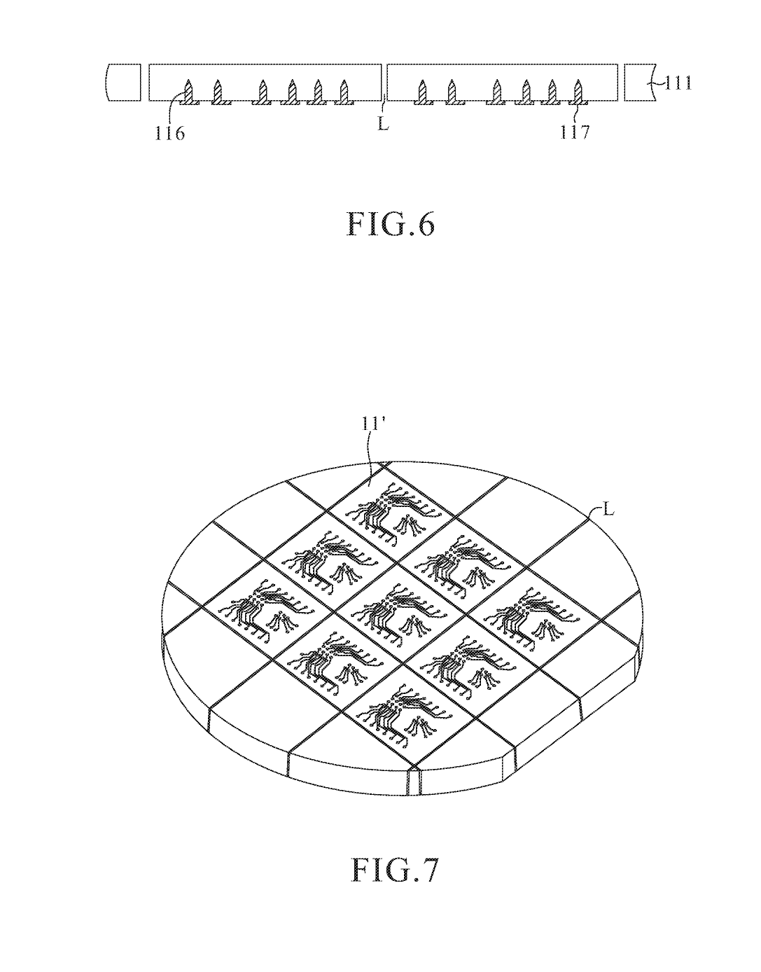

FIGS. 6 and 7 are cross-sectional and bottom perspective views, respectively, of the panel-scale structure of FIGS. 4 and 5 diced into individual pieces. The structure of FIGS. 4 and 5 is singulated into individual semi-finished interposer 11′ along dicing lines “L”.

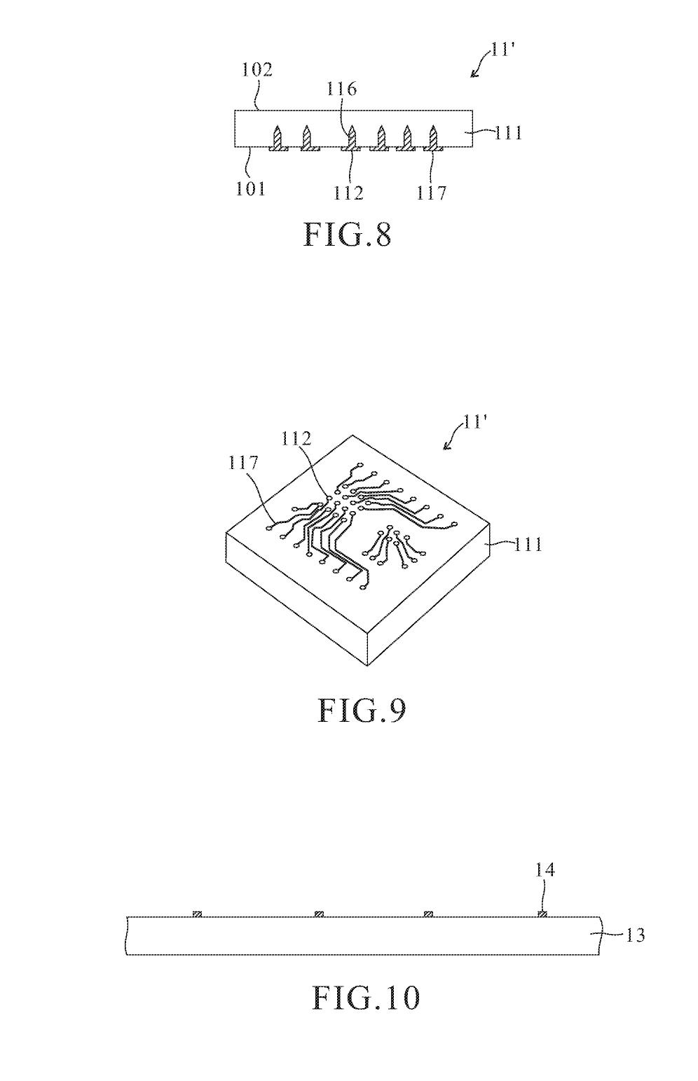

FIGS. 8 and 9 are cross-sectional and bottom perspective views, respectively, of an individual semi-finished interposer 11′ that includes a substrate 111, bond pads 112 and metallized vias 116. The metallized vias 116 are formed in the substrate 111 and electrically coupled to the bond pads 112 at the first surface 101 of the substrate 111.

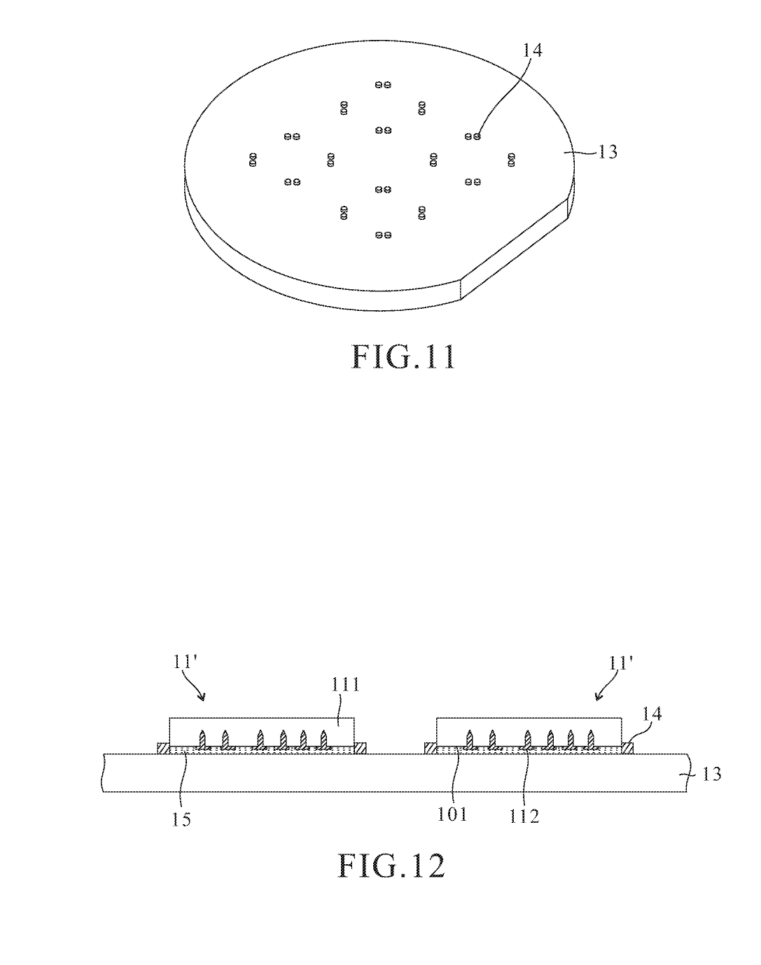

FIGS. 10 and 11 are cross-sectional and top perspective views, respectively, of the structure with multiple sets of alignment guides 14 on a sacrificial carrier 13. The sacrificial carrier 13 typically is made of copper, aluminum, iron, nickel, tin, stainless steel, or other metals or alloys, but any other conductive or non-conductive material also may be used. The thickness of the sacrificial carrier 13 preferably ranges from 0.1 to 2.0 mm The alignment guides 14 project from the sacrificial carrier 13 and can have a thickness of 5 to 200 microns. In this embodiment, the sacrificial carrier 13 has a thickness of 1.0 mm, whereas the alignment guides 14 have a thickness of 50 microns. For a conductive sacrificial carrier 13, the alignment guides 14 typically are formed on the sacrificial carrier 13 by pattern deposition of metal (such as copper), such as electroplating, electroless plating, evaporating, sputtering or their combinations using photolithographic process. Alternatively, if a non-conductive sacrificial carrier 13 is used, a solder mask or photo resist may be used to form the alignment guides 14. As shown in FIG. 11, each set of the alignment guides 14 consists of plural posts and conform to four corners of the subsequently disposed semi-finished interposer 11′ of FIG. 9. However, the alignment guide patterns are not limited thereto and can be in other various patterns against undesirable movement of the subsequently disposed semi-finished interposer 11′. For instance, the alignment guide 14 may consist of a continuous or discontinuous strip and conform to four sides, two diagonal corners or four corners of the semi-finished interposer 11′. Alternatively, the alignment guide 14 may laterally extend to the peripheral edges of the sacrificial carrier 13 and have inner peripheral edges that conform to the peripheral edges of the semi-finished interposer 11′.

FIG. 12 is a cross-sectional view of the structure with the semi-finished interposers 11′ of FIG. 8 attached to the sacrificial carrier 13 using an adhesive 15. The semi-finished interposers 11′ are attached to the sacrificial carrier 13 with its first surface 101 facing the sacrificial carrier 13 and each set of the alignment guides 14 laterally aligned with and in close proximity to the peripheral edges of each semi-finished interposer 11′. The placement accuracy of the semi-finished interposer 11′ is provided by the alignment guides 14. The alignment guides 14 extend beyond the first surface 101 of the semi-finished interposer 11′ in the upward direction and is located beyond and laterally aligned with the four corners of the semi-finished interposer 11′ in the lateral directions. As the alignment guides 14 are in close proximity to and conform to the four corners of the semi-finished interposer 11′ in lateral directions, any undesirable movement of the semi-finished interposer 11′ due to adhesive curing can be avoided. Preferably, a gap in between the alignment guides 14 and the semi-finished interposer 11′ is in a range of about 5 to 50 microns. Further, the semi-finished interposer 11′ can also be attached without the alignment guides 14.

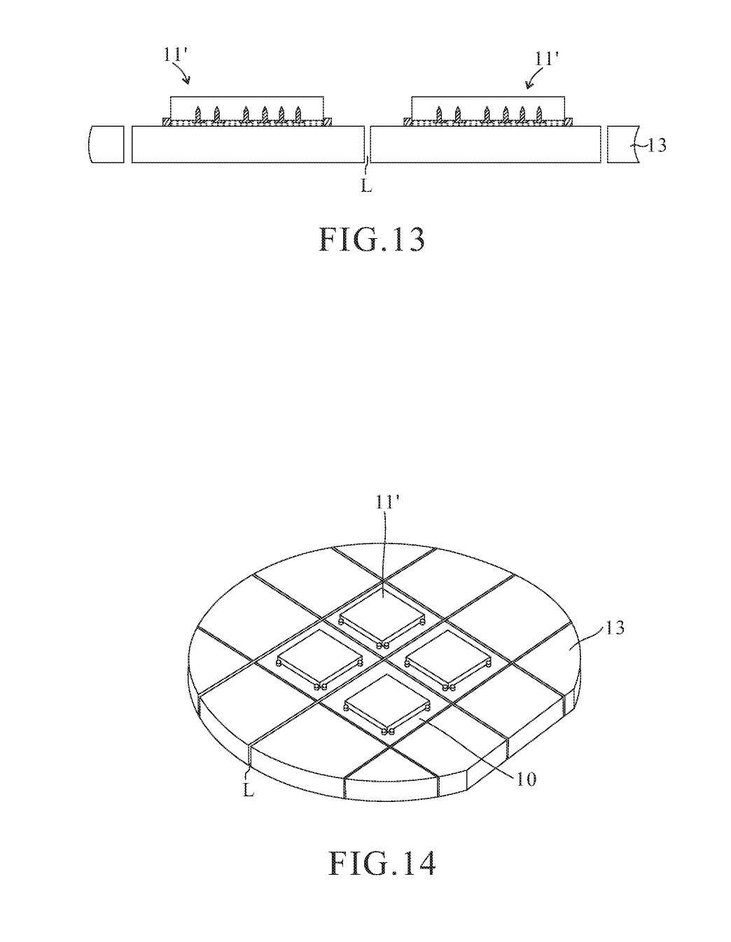

FIGS. 13 and 14 are cross-sectional and top perspective views, respectively, of the panel-scale structure of FIG. 12 diced into individual pieces. The structure of FIG. 12 is singulated into individual subcomponents 10 along dicing lines “L”.

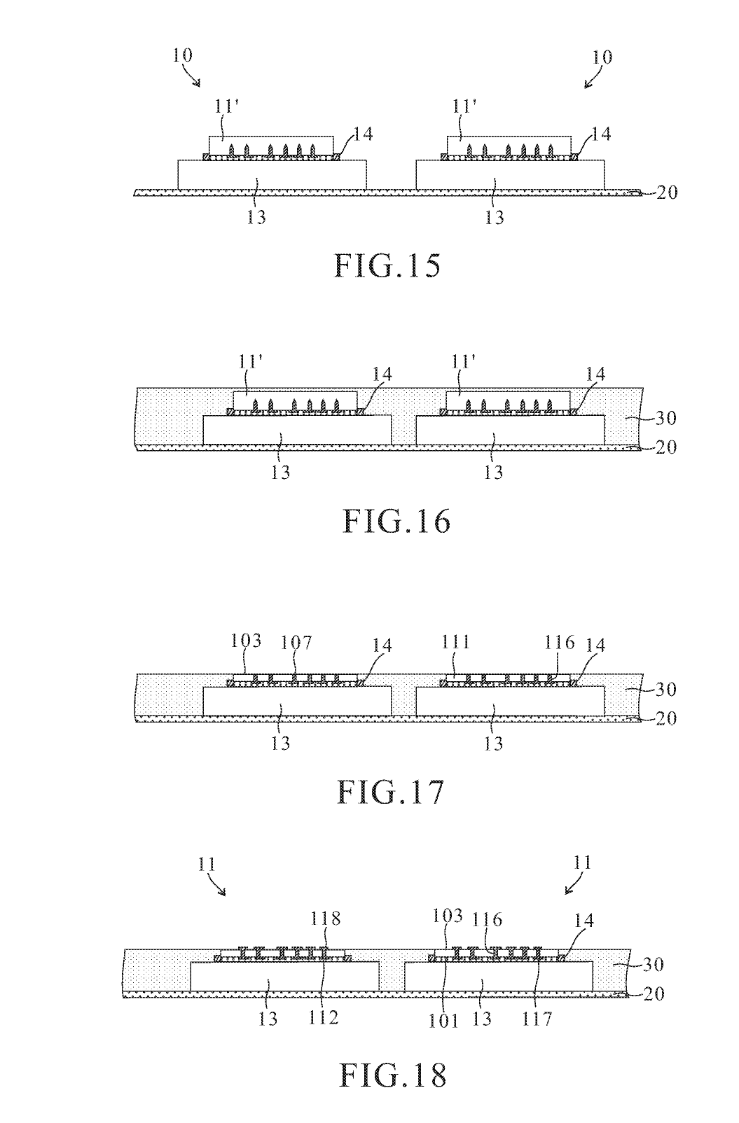

FIG. 15 is a cross-sectional view of the subcomponents 10 on a carrier film 20 with the sacrificial carriers 13 attached on the carrier film 20. The carrier film 20 typically is a tape, and the sacrificial carriers 13 are attached to the carrier film 20 by the adhesive property of the carrier film 20. Alternatively, the subcomponents 10 may be attached to the carrier film 20 by dispensing extra adhesive.

FIG. 16 is a cross-sectional view of the structure with a resin molded stiffener 30 deposited on the subcomponents 10 and the carrier film 20. The resin molded stiffener 30 can be provided by molding, resin coating or resin lamination. The resin molded stiffener 30 contacts and covers the semi-finished interposers 11′, the sacrificial carriers 13, the alignment guides 14 and the carrier film 20 from above, and surrounds and conformally coats sidewalls of the semi-finished interposers 11′ and the sacrificial carriers 13. In this embodiment, the resin molded stiffener 30 is made of a molding compound.

FIG. 17 is a cross-sectional view of the structure with the second ends 107 of the metallized vias 116 exposed from above. Top portions of the resin molded stiffener 30 and the substrate 111 are removed typically by lapping, grinding or laser to expose the second ends 107 of the metallized vias 116 from an exposed second surface 103 of the substrate 111. The exposed second surface 103 of the substrate 111 is substantially coplanar with the second ends 107 of the metallized vias 116 and the top surface of the resin molded stiffener 30.

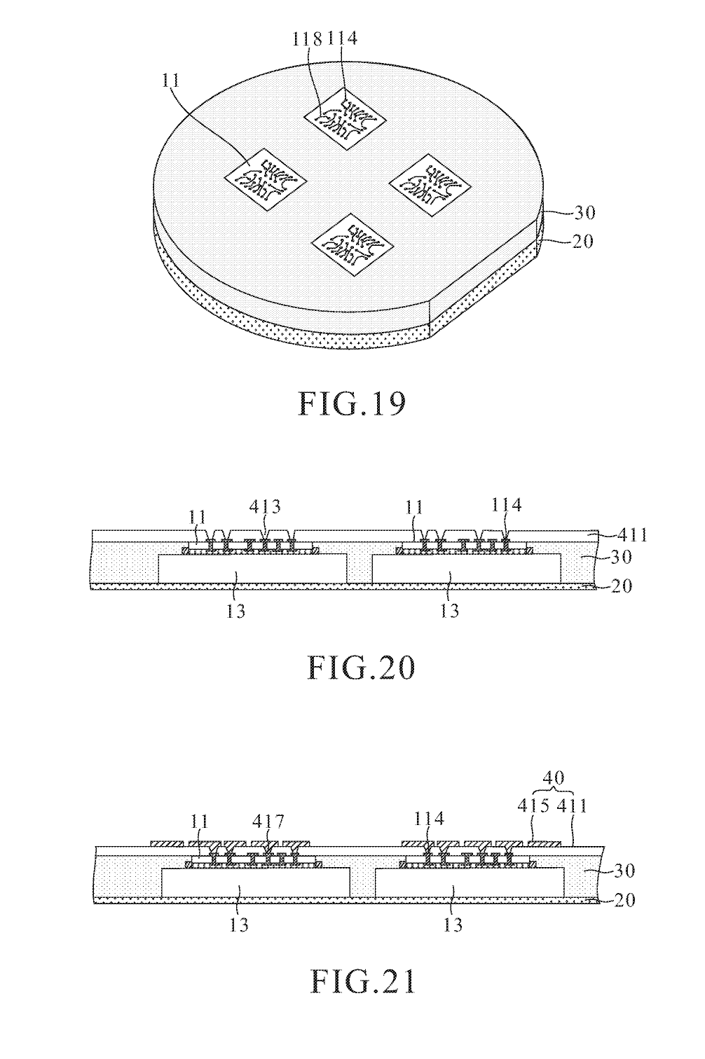

FIGS. 18 and 19 are cross-sectional and top perspective views, respectively, of the structure provided with top routing traces 118 by metal deposition and metal patterning process. The top routing traces 118 extend laterally on the second surface 103 of the substrate 111 and are electrically coupled to the second ends 107 of the metallized vias 116. As shown in FIG. 19, the top routing traces 118 include a patterned array of contact pads 114 that have larger pad size and pitch than those of the bond pads 112.

At this stage, the fabrication of interposers 11 is finished, and each finished interposer 11 includes bond pads 112 at its first surface 101, contact pads 114 at its opposite second surface 103, and metallized vias 116 electrically coupled to the bond pads 112 and the contact pads 114. Accordingly, the finished interposers 11 can provide a primary fan-out routing to ensure a higher manufacturing yield for the next level build-up circuitry interconnection.

FIG. 20 is a cross-sectional view of the structure with a dielectric layer 411 laminated/coated on the interposers 11 and the resin molded stiffener 30 and via openings 413 in the dielectric layer 411. The dielectric layer 411 contacts and covers and extends laterally on the interposers 11 and the resin molded stiffener 30 from above. The dielectric layer 411 typically has a thickness of 50 microns, and can be made of epoxy resin, glass-epoxy, polyimide, or the like. After the deposition of the dielectric layer 411, the via openings 413 are formed by numerous techniques, such as laser drilling, plasma etching and photolithography, and typically have a diameter of 50 microns. Laser drilling can be enhanced by a pulsed laser. Alternatively, a scanning laser beam with a metal mask can be used. The via openings 413 extend through the dielectric layer 411 and are aligned with the contact pads 114 of the interposers 11.

Referring now to FIG. 21, conductive traces 415 are formed on the dielectric layer 411 by metal deposition and metal patterning process. The conductive traces 415 extend from the contact pads 114 of the interposers 11 in the upward direction, fill up the via openings 413 to form conductive vias 417 in direct contact with the contact pads 114, and extend laterally on the dielectric layer 411. As a result, the conductive traces 415 can provide horizontal signal routing in both the X and Y directions and vertical routing through the via openings 413 and serve as electrical connections for the contact pads 114 of the interposers 11.

The conductive traces 415 can be deposited as a single layer or multiple layers by any of numerous techniques, such as electroplating, electroless plating, evaporating, sputtering, or their combinations. For instance, they can be deposited by first dipping the structure in an activator solution to render the dielectric layer 411 catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, the plated layer can be patterned to form the conductive traces 415 by any of numerous techniques, such as wet etching, electro-chemical etching, laser-assist etching, or their combinations, with an etch mask (not shown) thereon that defines the conductive traces 415.

At this stage, the formation of a build-up circuitry 40 on the interposers 11 and the resin molded stiffener 30 is accomplished. In this illustration, the build-up circuitry 40 includes a dielectric layer 411 and conductive traces 415.

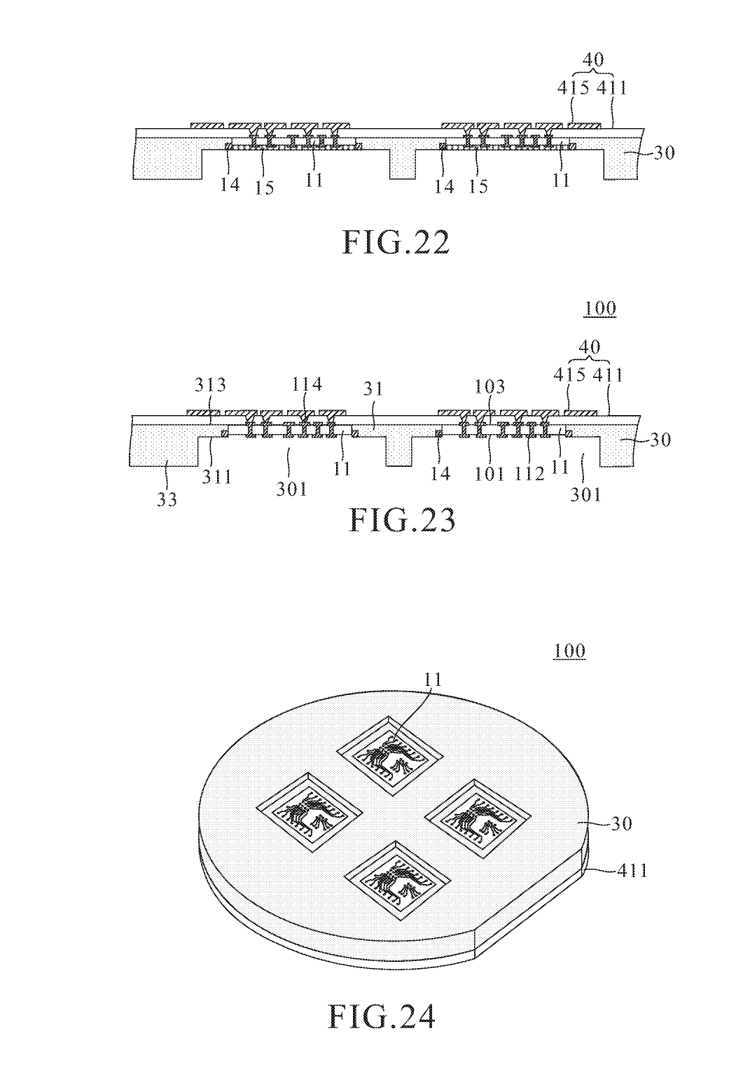

FIG. 22 is a cross-sectional view of the structure after removal of the carrier film 20 and the sacrificial carriers 13. The carrier film 20 is detached from the sacrificial carriers 13 and the resin molded stiffener 30, followed by removing the sacrificial carriers 13. The sacrificial carriers 13 can be removed by numerous techniques, such as wet chemical etching using acidic solution (e.g., ferric chloride, copper sulfate solutions) or alkaline solution (e.g., ammonia solution), electro-chemical etching, or mechanical process such as a drill or end mill followed by chemical etching Further, in some cases, the alignment guides 14 may be removed together with the sacrificial carriers 13.

FIGS. 23 and 24 are cross-sectional and bottom perspective views, respectively, of the structure after removal of the adhesive 15. The adhesive 15 is removed from the first surface 101 of the interposers 11 typically by etching techniques, such as reactive ion etching plasma etching, laser ablation or combination thereof. As a result, the bond pads 112 at the first surface 101 of the interposers 11 are exposed from cavities 301.

At this stage, a wiring board 100 is accomplished and includes interposers 11, alignment guides 14, a resin molded stiffener 30 and a build-up circuitry 40. In this illustration, the resin molded stiffener 30 includes a base 31 and a protruded portion 33 projecting from a first surface 311 of the base 31. As the adhesive 15 for the preceding step of interposer attachment practically has an almost negligible thickness, the first surface 311 of the base 31 is substantially coplanar with an external surface of the bond pads 112 of the interposer 11. Additionally, the second surface 103 of the interposer 11 is substantially coplanar with an opposite second surface 313 of the base 31.

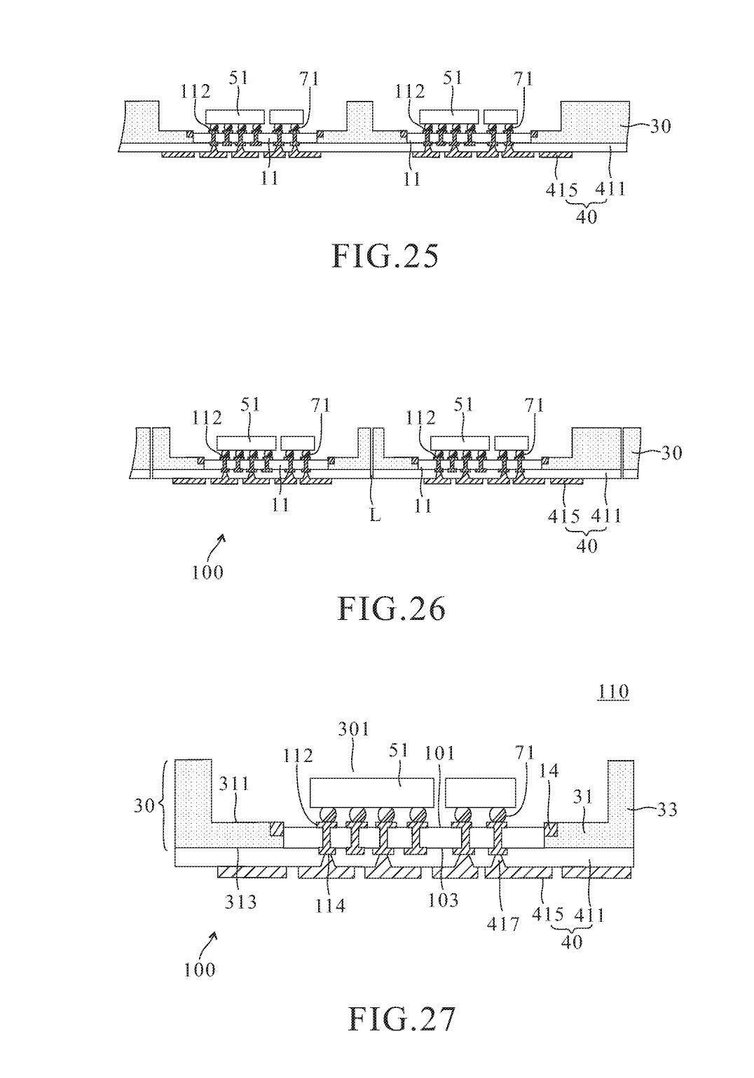

FIG. 25 is a cross-sectional view of the structure with semiconductor devices 51, illustrated as chips, mounted on the interposers 11. The semiconductor devices 51 are flip-chip mounted on the exposed bond pads 112 of the interposers 11 via solder bumps 71.

FIG. 26 is a cross-sectional view of the panel-scale structure of FIG. 25 diced into individual pieces. The panel-scale structure, having the semiconductor devices 51 electrically coupled to the panel-scale wiring board 100, is singulated into individual semiconductor assemblies 110 along dicing lines “L”.

FIG. 27 is a cross-sectional view of an individual semiconductor assembly 110 that includes a wiring board 100 and semiconductor devices 51. In this illustration, the wiring board 100 includes an interposer 11, an alignment guide 14, a resin molded stiffener 30 and a build-up circuitry 40.

The resin molded stiffener 30, consisting of a base 31 and a protruded portion 33, has a higher elastic modulus than that of the build-up circuitry 40, and can provide mechanical support and suppress warping and bending of the wiring board 100. In this illustration, the base 31 laterally surrounds peripheral edges of the interposer 11 and has a first surface 311 partially exposed from a cavity 301, whereas the protruded portion 33 projects from the first surface 311 of the base 31 and laterally surrounds the cavity 301. As such, the base 31 provides mechanical support for the interposer 11 and the build-up circuitry 40, whereas the protruded portion 33 provides thicker peripheral edges for the wiring board 100 and offers critical stiffness enhancement for the base 31 and the interposer 11.

The interposer 11 is laterally surrounded by the base 31, with its first surface 101 exposed from the cavity bottom and the alignment guide 14 around its first surface 101 and conforming to its four corners. The interposer 11 contains a pattern of traces that fan out from a finer pitch at the bond pads 112 to a coarser pitch at the contact pads 114. As a result, the interposer 11 can provide a primary fan-out routing for the semiconductor devices 51 assembled on the bond pads 112 exposed from the cavity bottom. Further, the interposer 11 has a smaller thermal expansion coefficient and higher modulus than that of the build-up circuitry 40 so as to ensure a reliable interface for chip connection.

The build-up circuitry 40 is disposed over the second surface 313 of the base 31 and substantially has a combined surface area of the interposer 11 and the base 31 of the resin molded stiffener 30. The build-up circuitry 40 includes conductive traces 415 laterally extending beyond peripheral edges of the interposer 11 and is electrically coupled to the contact pads 114 of the interposer 11 through the conductive vias 417 of the build-up circuitry 40 to provide fan-out routing for the interposer 11.

The semiconductor devices 51 are positioned within the cavity 301 and flip-chip mounted on the exposed bond pads 112 of the interposer 11 via solder bumps 71.

### Embodiment 2

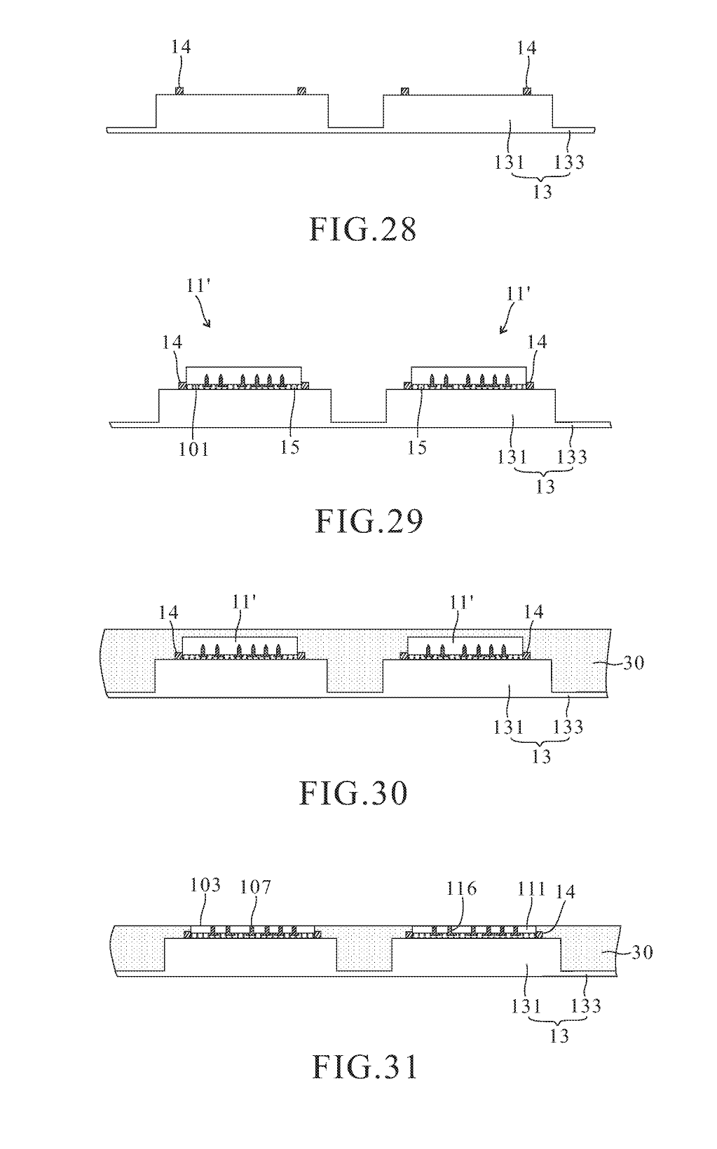

FIGS. 28-37 are schematic views showing another method of making a wiring board in which no carrier film is used in accordance with the second embodiment of the present invention.

For purposes of brevity, any description in Embodiment 1 above is incorporated herein insofar as the same is applicable, and the same description need not be repeated.

FIG. 28 is a cross-sectional view of the structure with multiple sets of alignment guides 14 on a sacrificial carrier 13. In this embodiment, the sacrificial carrier 13 is shaped to include multiple bump portions 131 and a flange portion 133 typically by etching or mechanical carving after the alignment guides 14 are formed on the sacrificial carrier 13. The bump portions 131 project from the flange portion 133 and can have a projecting height of 0.1 mm to 1.0 mm, whereas the flange portion 133 is located around the bottoms of the bump portions 131 and extends laterally from the bump portions 131. In this embodiment, each bump portion 131 has a projecting height of 0.3 mm from the flange portion 133, whereas each alignment guide 14 has a projecting height of 50 microns from the bump portion 131.

FIG. 29 is a cross-sectional view of the structure with the semi-finished interposers 11′ of FIG. 8 attached to the sacrificial carrier 13 using an adhesive 15. The semi-finished interposers 11′ are attached to the bump portions 131 of the sacrificial carrier 13 with its first surface 101 facing the sacrificial carrier 13 and the alignment guide 14 laterally aligned with and in close proximity to the peripheral edges of the semi-finished interposers 11′.

FIG. 30 is a cross-sectional view of the structure with a resin molded stiffener 30 deposited on the semi-finished interposers 11′ and the sacrificial carrier 13. The resin molded stiffener 30 contacts and covers the semi-finished interposers 11′ and the bump portions 131 and the flange portion 133 of the sacrificial carrier 13 from above, and surrounds and conformally coats sidewalls of the semi-finished interposers 11′ and the bump portions 131 of the sacrificial carrier 13.

FIG. 31 is a cross-sectional view of the structure with the second ends 107 of the metallized vias 116 exposed from above. Top portions of the resin molded stiffener 30 and the substrate 111 are removed to expose the second ends 107 of the metallized vias 116 from an exposed second surface 103 of the substrate 111. The exposed second surface 103 of the substrate 111 is substantially coplanar with the second ends 107 of the metallized vias 116 and the top surface of the resin molded stiffener 30.

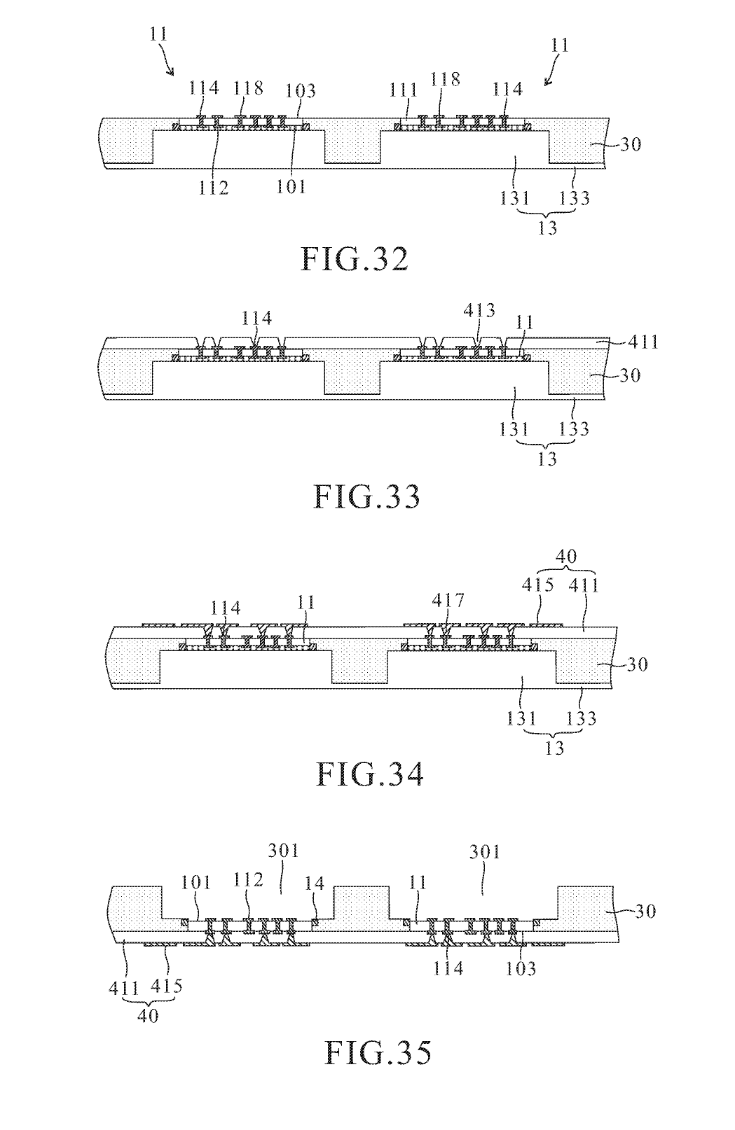

FIG. 32 is a cross-sectional view of the structure provided with top routing traces 118 by metal deposition and metal patterning process. The top routing traces 118 extend laterally on the second surface 103 of the substrate 111 and are electrically coupled to the second ends 107 of the metallized vias 116 and include a patterned array of contact pads 114.

At this stage, the fabrication of interposers 11 is finished, and each finished interposer 11 includes bond pads 112 at its first surface 101, contact pads 114 at its opposite second surface 103, and metallized vias 116 electrically coupled to the bond pads 112 and the contact pads 114.

FIG. 33 is a cross-sectional view of the structure with a dielectric layer 411 laminated/coated on the interposers 11 and the resin molded stiffener 30 and via openings 413 in the dielectric layer 411. The dielectric layer 411 contacts and covers and extends laterally on the interposers 11 and the resin molded stiffener 30 from above. The via openings 413 extend through the dielectric layer 411 and are aligned with the contact pads 114 of the interposers 11.

Referring now to FIG. 34, conductive traces 415 are formed on the dielectric layer 411 by metal deposition and metal patterning process. The conductive traces 415 extend from the contact pads 114 of the interposers 11 in the upward direction, fill up the via openings 413 to form conductive vias 417 in direct contact with the contact pads 114, and extend laterally on the dielectric layer 411.

FIG. 35 is a cross-sectional view of the structure after removal of the sacrificial carriers 13 and the adhesive 15. As a result, the bond pads 112 at the first surface 101 of the interposer 11 are exposed from cavities 301 and can serve as electrical contacts for chip connection. As mentioned in Embodiment 1, since the adhesive 15 used for interposer attachment practically has an almost negligible thickness, the resin molded stiffener 30 having a surface exposed from the cavities 301 and substantially coplanar with an external surface of the bond pads 112 of the interposers 11.

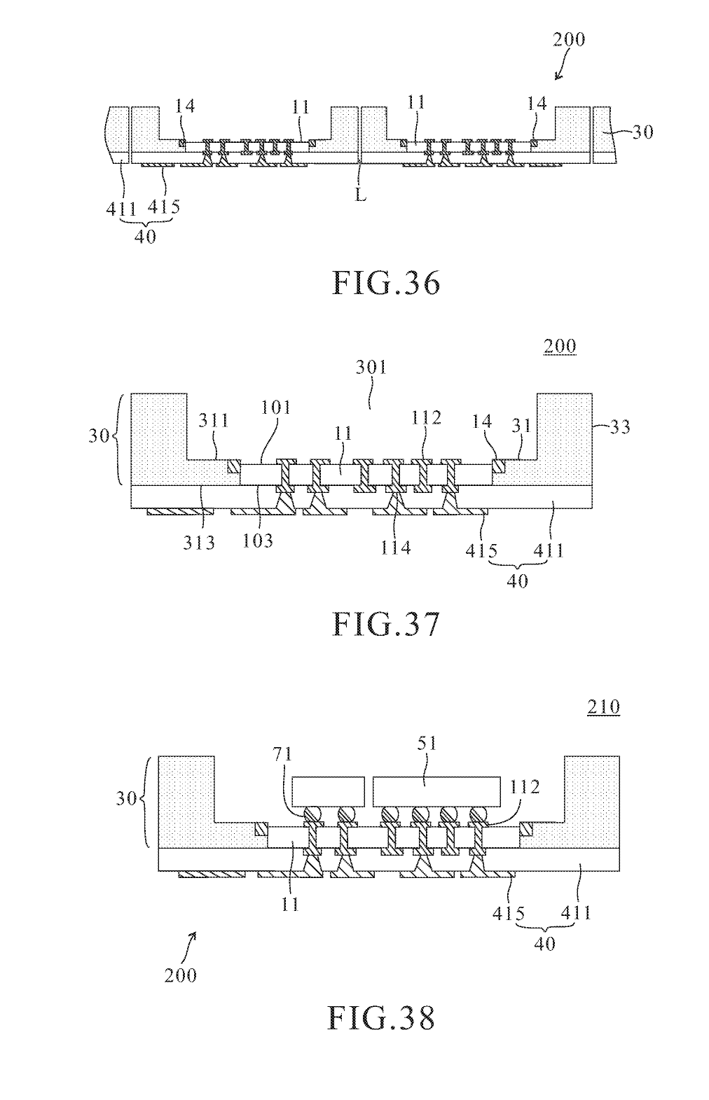

FIG. 36 is a cross-sectional view of the panel-scale structure of FIG. 35 diced into individual pieces. The panel-scale structure of FIG. 35 is singulated into individual wiring board 200 along dicing lines “L”.

FIG. 37 is a cross-sectional view of an individual wiring board 200 that includes an interposer 11, an alignment guide 14, a resin molded stiffener 30 and a build-up circuitry 40. In this illustration, the resin molded stiffener 30 includes a base 31 and a protruded portion 33, and the build-up circuitry 40 includes a dielectric layer 411 over the base 31 and conductive traces 415 electrically coupled to the contact pads 114 of the interposer 11.

The interposer 11 is laterally surrounded by the base 31 of the resin molded stiffener 30 with the alignment guide 14 around its first surface 101, and includes bond pads 112 exposed from the cavity 301 to provide electrical contacts from above for chip connection. The base 31 of the resin molded stiffener 30 laterally extends form sidewalls of the interposer 11 to peripheral edges of the wiring board 200, and has a first surface 311 and an opposite second surface 313 substantially coplanar with an external surface of the bond pads 112 and the second surface 103 of the interposer 11 in the upward and downward directions, respectively. The protruded portion 33 of the resin molded stiffener 30 projects from the first surface 311 of the base 31 and provides thicker peripheral edges for the wiring board 200. The build-up circuitry 40 is positioned over the second surface 313 of the base 31 and includes conductive traces 415 electrically coupled to the contact pads 114 of the interposer 11 and laterally extending beyond peripheral edges of the interposer 11 to provide fan-out routing for the interposer 11.

FIG. 38 is a cross-sectional view of a semiconductor assembly 210 with semiconductor devices 51, illustrated as chips, mounted on the wiring board 200 illustrated in FIG. 37. The semiconductor devices 51 are flip-chip mounted on the exposed bond pads 112 of the interposer 11 via solder bumps 71.

### Embodiment 3

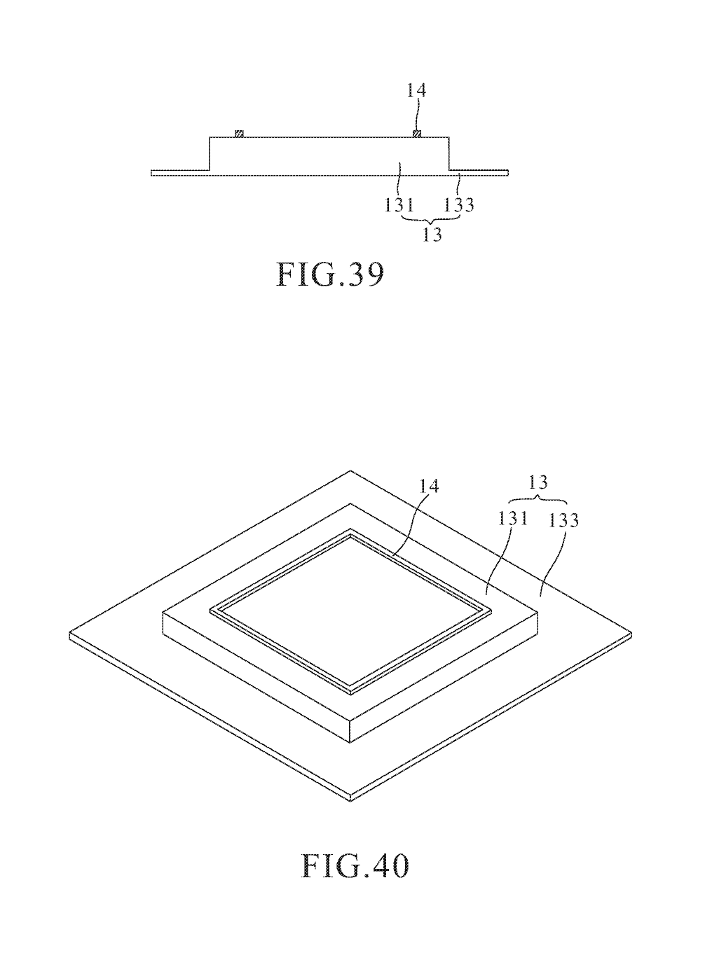

FIGS. 39-46 are schematic views showing yet another method of making a wiring board that includes a step of attaching a finished interposer to a sacrificial carrier in accordance with the third embodiment of the present invention.

For purposes of brevity, any description in aforementioned Embodiments above is incorporated herein insofar as the same is applicable, and the same description need not be repeated.

FIGS. 39 and 40 are cross-sectional and top perspective views, respectively, of the structure with an alignment guide 14 on a sacrificial carrier 13. In this embodiment, the sacrificial carrier 13 is shaped to include a bump portion 131 and a flange portion 133 before the alignment guide 14 is formed on the bump portion 131 of the sacrificial carrier 13. The bump portion 131 projects from the flange portion 133, whereas the flange portion 133 extends laterally from the bump portion 131. Further, as shown in FIG. 40, the alignment guide 14, projecting from the bump portion 131, consists of a continuous strip and conforms to four sides of a subsequently disposed interposer.

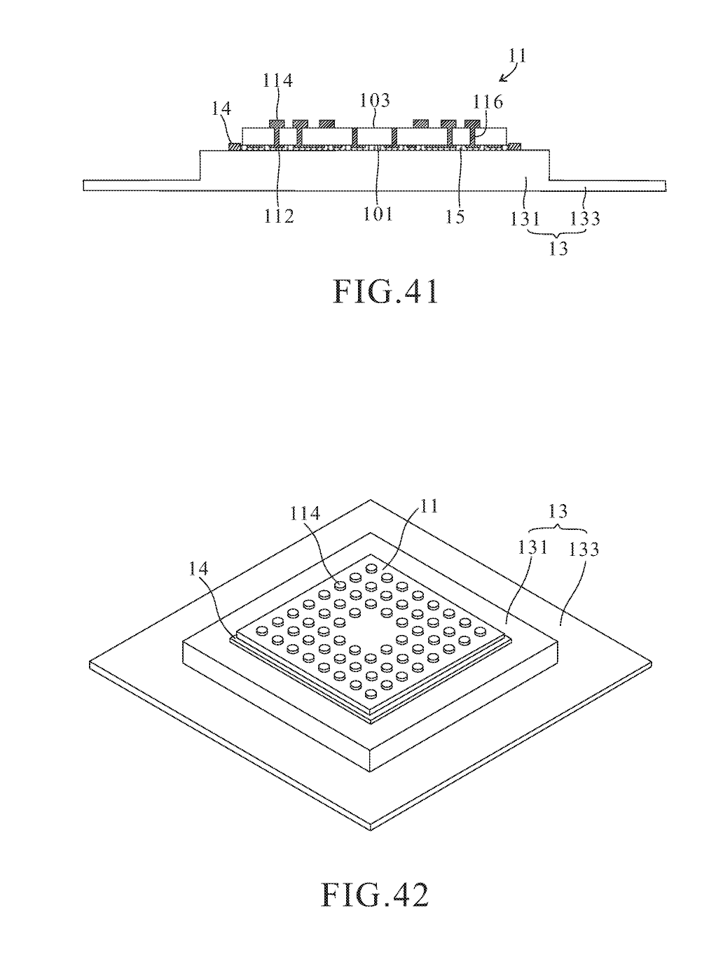

FIGS. 41 and 42 are cross-sectional and top perspective views, respectively, of the structure with an interposer 11 attached to the sacrificial carrier 13. The interposer 11 includes bond pads 112 at its first surface 101, contact pads 114 at its opposite second surface 103, and metallized vias 116 electrically coupled to the bond pads 112 and the contact pads 114. The interposer 11 can be silicon, glass or ceramic interposers, and has a thickness of 50 microns to 500 microns. In this embodiment, the thickness of the interposer 11 is 200 microns. The interposer 11 is attached to the bump portion 131 of the sacrificial carrier 13 using an adhesive 15, with its first surface 101 of the interposer 11 facing the sacrificial carrier 13 and in contact with the adhesive 15. Additionally, the interposer 11 can be placed at predetermined locations by the alignment guide 14 laterally aligned with and in close proximity to the peripheral edges of the interposer 11. As the alignment guides 14 extend from the bump portion 131 of the sacrificial carrier 13 and extend beyond the first surface 101 of the interposer 11 in the upward direction, the alignment guide 14 can confine the dislocation of the interposer 11 laterally. The interposer 11 can also be attached without the alignment guide 14. For instance, in the aspect of the interposer 11 having large pad size and pitch at its second surface 103, even if no alignment guide 14 is provided to ensure the placement accuracy of the interposer 11, it does not result in micro-via connection failure in the subsequent process of forming build-up circuitry on interposer 11.

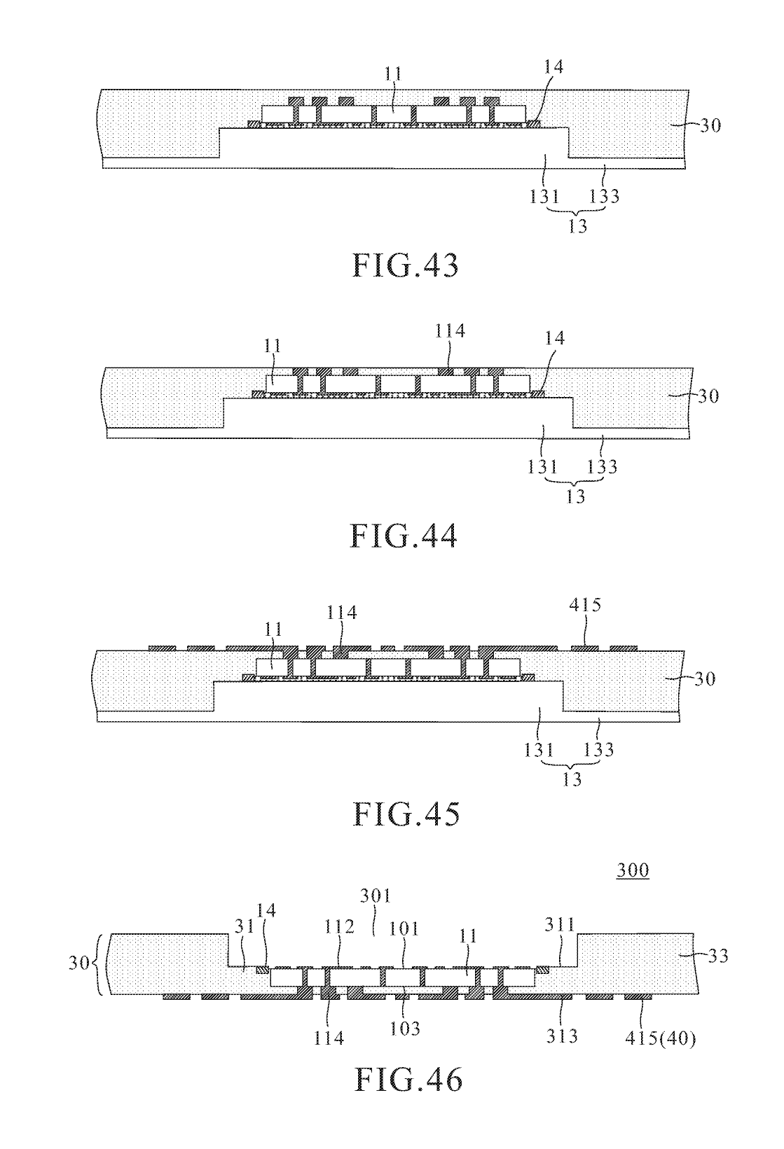

FIG. 43 is a cross-sectional view of the structure with a resin molded stiffener 30 deposited on the interposer 11 and the sacrificial carrier 13. The resin molded stiffener 30 contacts and covers the interposer 11 and the bump portion 131 and the flange portion 133 of the sacrificial carrier 13 from above, and surrounds and conformally coats sidewalls of the interposer 11 and the bump portion 131 of the sacrificial carrier 13.

FIG. 44 is a cross-sectional view of the structure with the contact pads 114 of the interposer 11 exposed from above. The resin molded stiffener 30 is partially removed to have a top surface substantially coplanar with an external surface of the contact pads 114 in the upward direction.

FIG. 45 is a cross-sectional view of the structure provided with conductive traces 415 by metal deposition and metal patterning process. The conductive traces 415 extend laterally on the contact pads 114 of the interposer 11 and the resin molded stiffener 30 and laterally extend beyond peripheral edges of the interposer 11.

FIG. 46 is a cross-sectional view of the structure after removal of the sacrificial carrier 13 and the adhesive 15. As a result, the bond pads 112 at the first surface 101 of the interposer 11 are exposed from a cavity 301 and can serve as electrical contacts for chip connection. As mentioned in Embodiment 1, since the adhesive 15 used for interposer attachment practically has an almost negligible thickness, the resin molded stiffener 30 having a surface exposed from the cavity 301 and substantially coplanar with an external surface of the bond pads 112 of the interposers 11.

Accordingly, as shown in FIG. 46, a wiring board 300 is accomplished and includes an interposer 11, an alignment guide 14, a resin molded stiffener 30 and a build-up circuitry 40. In this illustration, the resin molded stiffener 30 includes a base 31 and a protruded portion 33, and the build-up circuitry 40 includes conductive traces 415 over the base 31 and in direct contact with the contact pads 114 of the interposer 11.

The interposer 11 is laterally surrounded by the base 31 of the resin molded stiffener 30 with the alignment guide 14 around its first surface 101, and includes bond pads 112 exposed from the cavity 301. The base 31 of the resin molded stiffener 30 has a first surface 311 substantially coplanar with the external surface of the bond pads 112, and an opposite second surface 313 substantially coplanar with the external surface of the contact pads 114. The protruded portion 33 of the resin molded stiffener 30 projects from the first surface 311 of the base 31 and laterally surrounds the cavity 301. The build-up circuitry 40 is positioned over the second surface 313 of the base 31 and includes conductive traces 415 electrically coupled to the contact pads 114 of the interposer 11 and laterally extends on the second surface 313 of the base 31.

### Embodiment 4

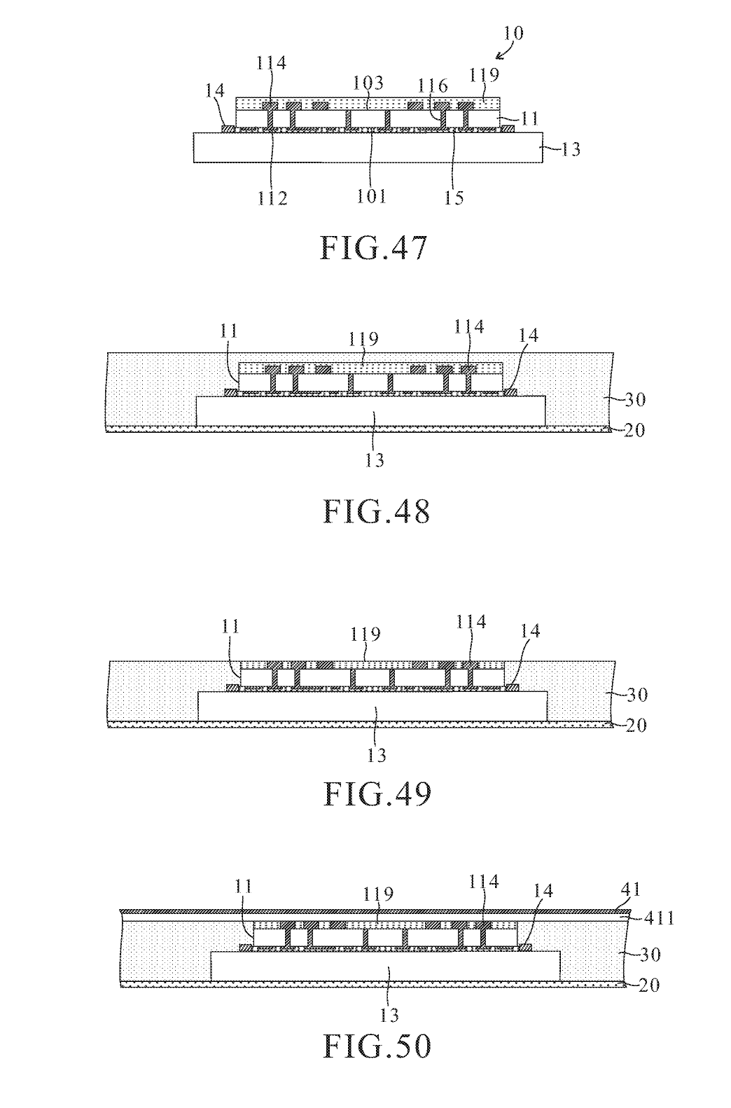

FIGS. 47-53 are schematic views showing yet another method of making a wiring board in which a carrier film is used and the interposer further includes a cover layer on its second surface in accordance with the fourth embodiment of the present invention.

For purposes of brevity, any description in aforementioned Embodiments above is incorporated herein insofar as the same is applicable, and the same description need not be repeated.

FIG. 47 is a cross-sectional view of a subcomponent 10 that includes an interposer 11, a sacrificial carrier 13 and an alignment guide 14. The interposer 11 is similar to that illustrated in FIG. 41, except that the interposer 11 further includes a cover layer 119 on its second surface 103 in this embodiment. The interposer 11 is attached to the sacrificial carrier 13 using an adhesive 15, with its first surface 101 facing the sacrificial carrier 13 and the alignment guide 14 in close proximity to peripheral edges of the interposer 11.

FIG. 48 is a cross-sectional view of the structure with the subcomponents 10 on a carrier film 20 and a resin molded stiffener 30 deposited on the subcomponents 10 and the carrier film 20. The subcomponent 10 is attached on the carrier film 20 with the sacrificial carrier 13 in direct contact with the carrier film 20. After the subcomponent 10 is placed on the carrier film 20, the resin molded stiffener 30 is deposited to cover the subcomponent 10 and the carrier film 20 from above.

FIG. 49 is a cross-sectional view of the structure with the contact pads 114 of the interposer 11 exposed from above. Top portions of the resin molded stiffener 30 and the cover layer 119 are removed to expose the contact pads 114 of the interposer 11 in the upward direction. In this illustration, the contact pads 114, the cover layer 119 and the resin molded stiffener 30 are substantially coplanar with each other at the top surfaces thereof.

FIG. 50 is a cross-sectional view of the structure with a dielectric layer 411 and a metal layer 41 laminated/coated on the interposer 11 and the resin molded stiffener 30. The dielectric layer 411 contacts and is sandwiched between the contact pads 114/cover layer 119 of the interposer 11 and the metal layer 41 and between the resin molded stiffener 30 and the metal layer 41.

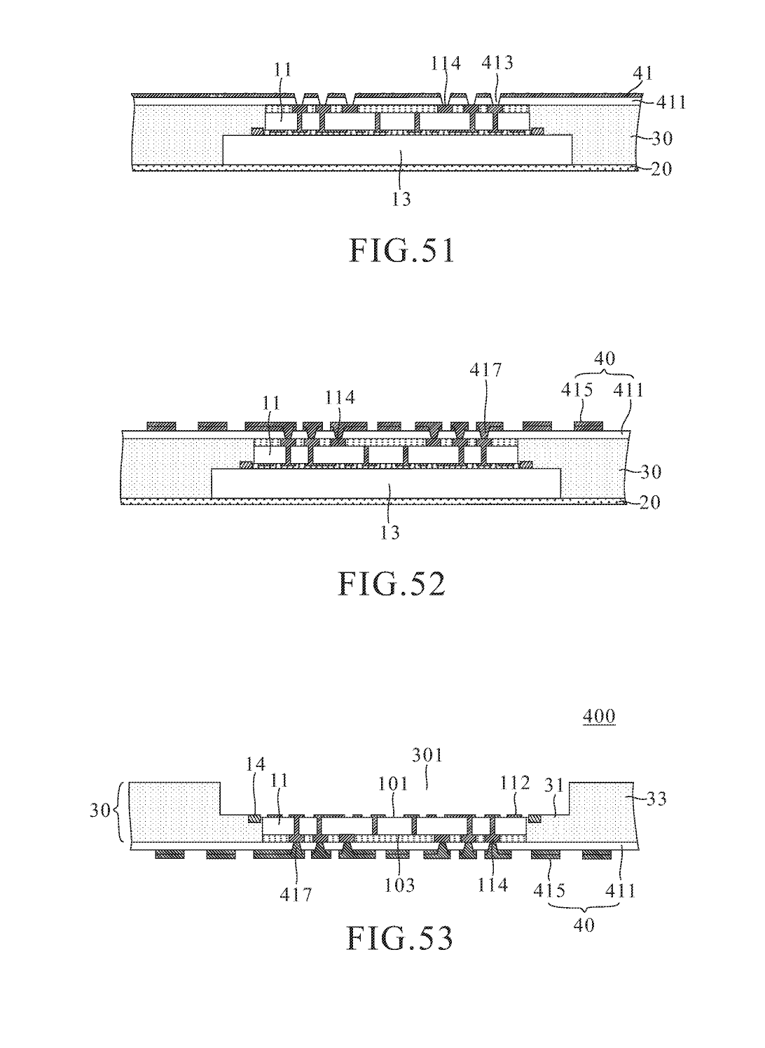

FIG. 51 is a cross-sectional view of the structure provided with the via openings 413 to expose the contact pads 114 of the interposer 11. The via openings 413 extend through the metal layer 41 and the dielectric layer 411 and are aligned with the contact pads 114 of the interposer 11.

Referring now to FIG. 52, conductive traces 415 are formed on the dielectric layer 411 by metal deposition and metal patterning process. The conductive traces 415 extend from the contact pads 114 of the interposer 11 in the upward direction, fill up the via openings 413 to form conductive vias 417 in direct contact with the contact pads 114, and extend laterally on the dielectric layer 411.

FIG. 53 is a cross-sectional view of the structure after removal of the carrier film 20, the sacrificial carrier 13 and the adhesive 15. As a result, the bond pads 112 at the first surface 101 of the interposer 11 are exposed from a cavity 301 and can serve as electrical contacts for chip connection. As mentioned in Embodiment 1, since the adhesive 15 used for interposer attachment practically has an almost negligible thickness, the resin molded stiffener 30 has a surface exposed from the cavity 301 and substantially coplanar with an external surface of the bond pads 112 of the interposers 11.

Accordingly, as shown in FIG. 53, a wiring board 400 is accomplished and includes an interposer 11, an alignment guide 14, a resin molded stiffener 30 and a build-up circuitry 40. In this illustration, the resin molded stiffener 30 includes a base 31 and a protruded portion 33, and the build-up circuitry 40 includes a dielectric layer 411 and conductive traces 415.

The interposer 11 is laterally surrounded by the base 31 of the resin molded stiffener 30 and includes bond pads 112 as electrical contacts at a bottom of the cavity 301 laterally surrounded by the protruded portion 33 of the resin molded stiffener 30. The combination of the interposer 11 and the base 31 of the resin molded stiffener 30 provides a flat platform for the deposition of the build-up circuitry 40, whereas the protruded portion 33 of the resin molded stiffener 30 provides critical stiffness enhancement for the interposer 11 and the base 31. The build-up circuitry 40 is electrically coupled to the contact pads 114 of the interposer 11 through conductive vias 417 and provides fan-out routing for the interposer 11.

The wiring boards and assemblies described above are merely exemplary. Numerous other embodiments are contemplated. In addition, the embodiments described above can be mixed-and-matched with one another and with other embodiments depending on design and reliability considerations. For instance, the wiring board may include multiple interposers and cavities in an array and each interposer is exposed from its corresponding cavity. Also, the build-up circuitry can include additional conductive traces to receive and route additional interposers, and additional alignment guides may be further provided and aligned with additional interposers. Additionally, a power/ground ring, resistor or/and capacitor may be also embedded in the resin molded stiffener.

As illustrated in the aforementioned embodiments, a distinctive wiring board is configured to exhibit improved reliability, which includes an interposer, a resin molded stiffener, a build-up circuitry, and an optional alignment guide. For the convenience of following description, the direction in which the first surface of the interposer faces is defined as the first direction, and the direction in which the second surface of the interposer faces is defined as the second direction.

The resin molded stiffener includes a base and a protruded portion projecting from a first surface of the base, and preferably is made of a material which has enough mechanical robustness and a higher elastic modulus than that of the build-up circuitry, such as molding compound. In a preferred embodiment, the base has a selected portion adjacent to and surrounding sidewalls of the interposer and not covered by the protruded portion in the first direction. The base and the protruded portion can be integrally formed as one piece by, for example, molding, resin coating or resin lamination. More specifically, after a finished or semi-finished interposer is attached on a detachable sacrificial carrier with its first surface facing the sacrificial carrier, the resin molded stiffener can be deposited to cover the sacrificial carrier in the second direction and laterally surround the sacrificial carrier and the finished or semi-finished interposer. As a result, the resin molded stiffener can be formed with a base around peripheral edges of the interposer and a protruded portion projecting from the base in the first direction and laterally covering sidewalls of the sacrificial carrier. In accordance with one preferred embodiment, the sacrificial carrier includes a bump portion and a flange portion, the bump portion projecting from the flange portion in the second direction and the flange portion extending laterally from the bump portion. After the finished or semi-finished interposer is attached on the bump portion of the sacrificial carrier, the resin molded stiffener covers the bump portion in the second direction and laterally surrounds sidewalls of the finished or semi-finished interposer to form the base, and also covers the flange portion in the second direction and laterally surrounds sidewalls of the bump portion to form the protruded portion. Alternatively, in accordance with another preferred embodiment, the sacrificial carrier is attached on a carrier film (typically an adhesive tape), followed by forming the resin molded stiffener that covers the sacrificial carrier in the second direction and laterally surrounds sidewalls of the finished or semi-finished interposer to form the base, and also covers the carrier film in the second direction and laterally surrounds sidewalls of sacrificial carrier to form the protruded portion. After the resin molded stiffener is deposited, the carrier film can be detached therefrom. As a result, the interposer can be laterally surrounded by and integrated with the base of the resin molded stiffener. As the sacrificial carrier together with the resin molded stiffener can provide a stable platform for forming the build-up circuitry, the removal of the sacrificial carrier preferably is carried out after the formation of the build-up circuitry. By removing the sacrificial carrier, the first surface of the interposer and the partial first surface of the base can be exposed from a bottom of a cavity laterally surrounded by the protruded portion. In a preferred embodiment, the base has a first surface substantially coplanar with an external surface of bond pads of the interposer in the first direction, and an opposite second surface substantially coplanar with the second surface of the interposer substrate or an external surface of the contact pads of the interposer in the second direction. The base laterally extends from sidewalls of the interposer to peripheral edges of the wiring board and has a larger surface area than that of the protruded portion, whereas the protruded portion partially covers the first surface of the base in the first direction and preferably has a projecting height of 0.1 mm to 2.0 mm As a result, the base provides mechanical support for the interposer and the build-up circuitry, and the protruded portion provides thicker peripheral edges for the wiring board and critical stiffness enhancement for the base and the interposer to suppress warping and bending of the wiring board.

The interposer can be made of a silicon, glass or ceramic, and may be finished or semi-finished when it is attached to the sacrificial carrier. By interposer backside process including grinding and circuitry formation, the semi-finished interposer can be fabricated into the finished-interposer that contain a pattern of traces that fan out from a finer pitch at its first surface to a coarser pitch at its second surface. Accordingly, the interposer can provide primary fan-out routing/interconnection for a semiconductor device to be assembled thereon. In a preferred embodiment, as the contact pads of the interposer have larger pad size than that of the bond pads thereof, micro-via connection failure in the subsequent formation of the build-up circuitry can be avoided. Additionally, as the interposer is typically made of a high elastic modulus material with CTE (coefficient of thermal expansion) approximately equal to that of the chip (for example, 3 to 10 ppm per degree Centigrade), internal stresses in chip and its electrical interconnection caused by CTE mismatch can be largely compensated or reduced. Further, in the step of attaching the finished or semi-finished interposer on the sacrificial carrier, the finished or semi-finished interposer can be placed at predetermined locations by an alignment guide projecting from the sacrificial carrier. In a preferred embodiment, the alignment guide extends from a surface of the sacrificial carrier and extends beyond the first surface of the finished or semi-finished interposer in the second direction. As such, the placement accuracy of the finished or semi-finished interposer can be provided by the alignment guide that is laterally aligned with and in close proximity to the peripheral edges of the finished or semi-finished interposer. The alignment guide can have various patterns against undesirable movement of the finished or semi-finished interposer. For instance, the alignment guide can include a continuous or discontinuous strip or an array of posts. Alternatively, the alignment guide may laterally extend to the peripheral edges of the sacrificial carrier and have inner peripheral edges that conform to the peripheral edges of the finished or semi-finished interposer. Specifically, the alignment guide can be laterally aligned with four lateral surfaces of the finished or semi-finished interposer to define an area with the same or similar topography as the finished or semi-finished interposer and prevent the lateral displacement of the finished or semi-finished interposer. For instance, the alignment guide can be aligned along and conform to four sides, two diagonal corners or four corners of the finished or semi-finished interposer so as to confine the dislocation of the finished or semi-finished interposer laterally. Besides, the alignment guide around the first surface of the finished or semi-finished interposer preferably has a height in a range of 5-200 microns, and may be simultaneously removed while removing the sacrificial carrier.

The build-up circuitry is formed over the second surfaces of the interposer and the base of the resin molded stiffener and electrically coupled to the contact pads of the interposer. In a preferred embodiment, the build-up circuitry laterally extends beyond the peripheral edges of the interposer, and further laterally extends to peripheral edges of the wiring board to substantially have a combined surface area of the interposer and the base of the resin molded stiffener. As such, the build-up circuitry has a larger surface area than that of the interposer and can provide fan-out routing/interconnection for the interposer. Specifically, the build-up circuitry can include conductive traces in direct contact with the second surface of the base and the contact pads of the interposer, or include a dielectric layer on the interposer and the resin molded stiffener and conductive traces that fill up via openings in the dielectric layer and extend laterally on the dielectric layer. As a result, the electrical connection between the build-up circuitry and interposer can be devoid of soldering material. Also, the interface between the build-up circuitry and the resin molded stiffener can be devoid of solder or adhesive.

The build-up circuitry can further include additional dielectric layers, additional via openings, and additional conductive traces if needed for further signal routing. The dielectric layer and the conductive traces are serially formed in an alternate fashion, and the outmost conductive traces can respectively accommodate conductive joints, such as solder balls, for electrical communication and mechanical attachment with another electronic device.

The present invention also provides a semiconductor assembly in which a semiconductor device is electrically coupled to the bond pads of the aforementioned wiring board. Specifically, the semiconductor device can be positioned in the cavity of the wiring board and electrically connected to the wiring board using various using a wide variety of connection media such as bumps on the bond pads of the wiring board. The semiconductor device can be a packaged or unpackaged chip. For instance, the semiconductor device can be a bare chip, or a wafer level packaged die, etc. Alternatively, the semiconductor device can be a stacked-die chip. Optionally, a filler material can be further provided to fill the gap between the semiconductor device and the interposer of the wiring board.

The term “cover” refers to incomplete or complete coverage in a vertical and/or lateral direction. For instance, in the cavity-up position, the build-up circuitry covers the interposer in the downward direction regardless of whether another element is between the interposer and the build-up circuitry.

The phrases “mounted on” and “attached on” include contact and non-contact with a single or multiple element(s). For instance, the interposer is attached on the sacrificial carrier regardless of whether it is separated from the sacrificial carrier by an adhesive.

The phrase “aligned with” refers to relative position between elements regardless of whether elements are spaced from or adjacent to one another or one element is inserted into and extends into the other element. For instance, the alignment guide is laterally aligned with the interposer since an imaginary horizontal line intersects the alignment guide and the interposer, regardless of whether another element is between the alignment guide and the interposer and is intersected by the line, and regardless of whether another imaginary horizontal line intersects the interposer but not the alignment guide or intersects the alignment guide but not the interposer. Likewise, the via openings are aligned with the contact pads of the interposer.

The phrase “in close proximity to” refers to a gap between elements not being wider than the maximum acceptable limit. As known in the art, when the gap between the interposer and the alignment guide is not narrow enough, the location error of the interposer due to the lateral displacement of the interposer within the gap may exceed the maximum acceptable error limit. In some cases, once the location error of the interposer goes beyond the maximum limit, it is impossible to align the predetermined portion of the interposer with a laser beam, resulting in the electrical connection failure between the interposer and the buildup circuitry. According to the contact pad size of the interposer, those skilled in the art can ascertain the maximum acceptable limit for a gap between the interposer and the alignment guide through trial and error to ensure the conductive vias being aligned with the contact pads of the interposer. Thereby, the description “the alignment guide is in close proximity to the peripheral edges of the interposer (or the semi-finished interposer)” means that the gap between the peripheral edges of the interposer (or the semi-finished interposer) and the alignment guide is narrow enough to prevent the location error of the interposer (or the semi-finished interposer) from exceeding the maximum acceptable error limit. For instance, the gaps in between the interposer (or the semi-finished interposer) and the alignment guide may be in a range of about 5 to 50 microns,

The phrases “electrical connection” and “electrically coupled” refer to direct and indirect electrical connection. For instance, the conductive traces of the build-up circuitry directly contact and are electrically connected to the contact pads of the interposer, and are spaced from and electrically connected to the bond pads of the interposer by the metallized vias of the interposer.

The “first direction” and “second direction” do not depend on the orientation of the wiring board, as will be readily apparent to those skilled in the art. For instance, the first surfaces of the interposer and the base of the resin molded stiffener face the first direction and the second surfaces of the interposer and the base of the resin molded stiffener face the second direction regardless of whether the wiring board is inverted. Thus, the first and second directions are opposite one another and orthogonal to the lateral directions. Furthermore, the first direction is the upward direction and the second direction is the downward direction in the cavity-up position, and the first direction is the downward direction and the second direction is the upward direction in the cavity-down position.

The wiring board according to the present invention has numerous advantages. For instance, the resin molded stiffener can provide an anti-warping platform for the build-up circuitry formation thereon to suppress warping and bending of the wiring board. The interposer provides a primary fan-out routing/interconnection and a CTE-matched interface for a semiconductor device to be assembled thereon. The build-up circuitry provides a fan-out routing/interconnection for the interposer. As such, a semiconductor device with fine pads can be electrically coupled to one side of the interposer with pad pitch that matches the semiconductor device, and the build-up circuitry is electrically coupled to the other side of the interposer with larger pad pitch and further enlarges the pad size and pitch of the semiconductor device. The alignment guide can provide critical placement accuracy for the interposer. By the mechanical robustness of the resin molded stiffener, the warping problem can be resolved. The wiring board made by this method is reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. A wiring board with embedded interposer integrated with stiffener, comprising:
a resin molded stiffener that includes a base and a protruded portion projecting from a first surface of the base;
an interposer that includes bond pads at a first surface thereof, contact pads at an opposite second surface thereof, and metallized vias electrically coupled to the bond pads and the contact pads, wherein the interposer is laterally surrounded by the base with the first surface of the interposer facing the same direction as the first surface of the base and being not covered by the base; and
a build-up circuitry over an opposite second surface of the base, wherein the build-up circuitry is electrically coupled to the contact pads of the interposer and includes at least one conductive trace laterally extending beyond peripheral edges of the interposer.

2. The wiring board of claim 1, wherein the resin molded stiffener has a higher elastic modulus than that of the build-up circuitry.

3. The wiring board of claim 1, wherein the interposer has a smaller surface area than that of the build-up circuitry.

4. The wiring board of claim 1, wherein the interposer has a smaller thermal expansion coefficient than that of the build-up circuitry.

5. A method of making a wiring board with embedded interposer intergrated with stiffener, comprising:
providing a semi-finished interposer that includes a substrate having a first surface and an opposite second surface, bond pads at the first surface of the substrate, and metallized vias, each of which is formed in the substrate and has a first end electrically coupled to the bond pads and an opposite second end spaced from the second surface of the substrate;
attaching the semi-finished interposer on a sacrificial carrier using an adhesive, with the first surface of the substrate facing the sacrificial carrier;
forming a resin molded stiffener that covers the sacrificial carrier and laterally surrounds the semi-finished interposer and the sacrificial carrier;
removing portions of the resin stiffener and the semi-finished interposer to expose the second ends of the metallized vias with the substrate having an exposed second surface substantially coplanar with the second ends of the metallized vias;
forming contact pads at the exposed second surface of the substrate to finish fabrication of an interposer that includes the bond pads and the contact pads respectively on opposite first and second surfaces thereof and the metallized vias electrically coupled to the bond pads and the contact pads;
forming a build-up circuitry that covers the second surface of the interposer and the resin molded stiffener and is electrically coupled to the contact pads of the interposer and includes at least one conductive trace laterally extending beyond peripheral edges of the interposer; and
removing the sacrificial carrier and the adhesive to expose the bond pads of the interposer.

6. The method of claim 5, wherein the semi-finished interposer is attached on the sacrificial carrier, with an alignment guide projecting from the sacrificial carrier and extending beyond the first surface of the substrate and being laterally aligned with and in close proximity to peripheral edges of the semi-finished interposer.

7. The method of claim 5, further comprising a step of attaching the sacrificial carrier on a carrier film before the step of forming the resin molded stiffener.

8. The method of claim 5, wherein (i) the sacrificial carrier includes a bump portion and a flange portion, the bump portion projecting from the flange portion, and the flange portion extending laterally from the bump portion, (ii) the semi-finished interposer is attached on the bump portion of the sacrificial carrier, and (iii) the resin molded stiffener covers the bump portion and the flange portion of the sacrificial carrier and laterally surrounds the semi-finished interposer and the bump portion of the sacrificial carrier.

9. A method of making a wiring board with embedded interposer integrated with stiffener, comprising:
providing an interposer that includes bond pads at a first surface thereof, contact pads at an opposite second surface thereof, and metallized vias electrically coupled to the bond pads and the contact pads;
attaching the interposer on a sacrificial carrier using an adhesive, with the first surface of the interposer facing the sacrificial carrier;
forming a resin molded stiffener that covers the sacrificial carrier and laterally surrounds the interposer and the sacrificial carrier;
forming a build-up circuitry that covers the second surface of the interposer and the resin molded stiffener and is electrically coupled to the contact pads of the interposer and includes at least one conductive trace laterally extending beyond peripheral edges of the interposer; and
removing the sacrificial carrier and the adhesive to expose the bond pads of the interposer.

10. The method of claim 9, wherein the interposer is attached on the sacrificial carrier, with an alignment guide projecting from the sacrificial carrier and extending beyond the first surface of the interposer and being laterally aligned with and in close proximity to peripheral edges of the interposer.

11. The method of claim 9, further comprising a step of attaching the sacrificial carrier on a carrier film before the step of forming the resin molded stiffener.

12. The method of claim 9, wherein (i) the sacrificial carrier includes a bump portion and a flange portion, the bump portion projecting from the flange portion, and the flange portion extending laterally from the bump portion, (ii) the interposer is attached on the bump portion of the sacrificial carrier, and (iii) the resin molded stiffener covers the bump portion and the flange portion of the sacrificial carrier and laterally surrounds the interposer and the bump portion of the sacrificial carrier.
